(19) United States
(12) Patent Application Publication
(10) Pub. No.: US 2012/0301991 A1
(43) Pub. Date: Nov. 29, 2012

(54) COMPOSITION SUITABLE FOR USE AS A CROSS-LINKING MASTERBATCH INCLUDING A FUNCTIONAL POLYOLEFIN

(75) Inventors: Samuel Devisme, Rouen (FR); Catherine Corfias-Zuccalli, Pont-audemer (FR)

(73) Assignee: ARKEMA FRANCE, Colombes (FR)

(21) Appl. No.: 13/511,054

(22) PCT Filed: Nov. 24, 2010
(86) PCT No.: PCT/FR10/52499

§ 371 Date: Aug. 8, 2012

(30) Foreign Application Priority Data
Dec. 3, 2009 (FR) 0958622

(51) Int. Cl. C08L 37/00; H01L 31/18; C09D 137/00

(52) U.S. Cl. 438/64; 525/327.4; 524/517; 257/E31.117

(57) ABSTRACT

A composition including a mixture of a cross-linking agent and a first polyolefin including a functional monomer selected from among unsaturated carboxylic diacid or carboxylic acid anhydrides, the unsaturated carboxylic acids and the unsaturated epoxides being suitable for cross-linking with a second polyolefin in order to form an assembly adhered to a substrate, said assembly and the substrate forming an integral structure having two separate layers, characterized in that the amount of cross-linking agent is no lower than 5% of the total weight of the composition. Said masterbatch enables, even in the absence of silanes, cross-linking of polymers, in particular polyolefins, in order to increase the adhesive capacity thereof to substrates such as polymers, metals, metal oxides or silicon. Said masterbatch can be used in particular for encapsulating photovoltaic cells.

### FIELD OF THE INVENTION

The present invention relates to a novel composition based on a functional polyolefin and comprising a cross-linking agent at high concentration.

This composition may be used as a masterbatch for cross-linking polymers. More particularly, this composition can advantageously be used for producing films encapsulating photovoltaic cells.

### PRIOR ART

Organic peroxides are commonly used for cross-linking thermoplastic resins or elastomers, these resins and elastomers being grouped together in the present description under the term “polymers”. In order to cross-link a polymer, a peroxide is generally blended with the polymer to be cross-linked in a first step, which is followed by a second step consisting in forming the polymer and a third step consisting in cross-linking, for example by heat treatment.

At ambient temperature, peroxides can be in liquid or solid form. When the peroxides are blended with these polymers, they are blended at high temperature, i.e. at a temperature above the softening point of the polymer, for example by extrusion or kneading; the peroxides are then generally in a liquid form.

One problem is that the peroxides in this liquid form are difficult to blend with the polymer and a phenomenon of demixing of the peroxide can be observed. A second problem is that the introduction of the peroxides requires sophisticated equipment in order to allow precise metering of the amount of peroxides to be introduced.

In order to facilitate the blending of peroxides with the polymer to be cross-linked, compositions comprising an additional polymer and peroxides in high concentration, well known under the name “masterbatch”, can be used.

U.S. Pat. No. 5,589,526 describes, for example, a master-batch comprising an elastomeric polymer such as the copolymer of ethylene and of vinyl acetate, from 30 to 50% by weight of the composition of an organic peroxide, a plasticizer, a polyoctenamer and also fillers. The masterbatch described is produced using a mixer for thermoplastics by melting the polymers with the plasticizer and adding the peroxide and then the fillers. The masterbatch does not comprise any functional polyolefin.

U.S. Pat. No. 3,594,342 describes a process for producing cross-linked polyethylene in which an oligomer of a copolymer of ethylene and of vinyl acetate or of a copolymer of ethylene and of acrylic ester is blended with a peroxide in order to form a masterbatch, which is then blended with a polyethylene in the molten state. The masterbatch does not comprise any functional polyolefin.

One of the fields in which it is necessary to cross-link polymers is the field of photovoltaic modules, in particular for the part encapsulating the photovoltaic cells.

A photovoltaic module comprises a “photovoltaic cell unit”, this cell unit being capable of converting light energy into electricity. A conventional photovoltaic cell unit has been represented in FIG. 1; this photo-voltaic cell unit 10 comprises cells 12, one cell containing a photovoltaic sensor 14, generally based on silicon treated in order to obtain photoelectric properties, in contact with electron collectors 16 placed above (upper collectors) and below (lower collectors) the photovoltaic sensor. The upper collectors 16 of one cell are connected to the lower collectors 16 of another cell 12 via conducting bars 18, generally consisting of an alloy of metals. All these cells 12 are connected to one another, in series and/or in parallel, to form the photovoltaic cell unit 10. When the photovoltaic cell unit 10 is placed under a light source, it delivers a continuous electric current, which can be recovered at the terminals 19 of the cell unit 10.

With reference to FIG. 2, the solar module 20 comprises the photovoltaic cell unit 10 of FIG. 1 encased in an “encapsulant” 22. An upper protective layer 24 and a lower protective film 26, also known as “backsheet”, are placed on either side of the encapsulated cell unit.

The encapsulant 22 must perfectly match the shape of the space existing between the photovoltaic cell unit and the protective layers 24 and 26 in order to avoid the presence of air, which would limit the output of the solar module. The encapsulant 22 must also prevent contact of the cells 12 with atmospheric oxygen and water, in order to limit corrosion thereof. In order to provide these various properties, this encapsulant is generally a composition comprising a polyolefin modified with a coupling agent in order to “encapsulate” the photovoltaic cell unit 10. In order to modify this polyolefin of the encapsulant, the coupling agents are added in combination with a cross-linking agent, which also makes it possible to prevent any creep of the encapsulant over time. The coupling agents are products generally chosen from organic titanates and silanes; the cross-linking agents are generally chosen from organic peroxides.

Moreover, during the processing of photovoltaic panels, the components are generally assembled by laminating, and the panel is vacuum-drawn by means of a silicone membrane. However, this silicone membrane has a tendency to decompose on contact with these coupling agents. This is a major problem for manufacturers of photovoltaic modules at the current time because these silicone membranes are expensive and production has to be stopped for the time taken to replace them. Furthermore, the coupling agents have a tendency to hydrolyze on contact with moisture and to lose their activity over time.

Document EP 1956661 A1 describes a masterbatch, as a mixture with a silane-modified polyethylene, used in photovoltaic cell encapsulants. This masterbatch comprises a metallocene polyethylene having a particular density, a UV absorber, a light stabilizer and a heat stabilizer, and comprises neither peroxide nor coupling agent.

It is therefore also necessary to find new solutions for solving at least one of the drawbacks mentioned above.

### SUMMARY OF THE INVENTION

A subject of the invention is thus a novel composition comprising a mixture of a cross-linking agent and a first polyolefin comprising a functional monomer X selected from unsaturated carboxylic acid or dicarboxylic acid anhydrides, unsaturated carboxylic acids and unsaturated epoxides, capable of being cross-linked with a second polyolefin in order to form an assembly adhered to a substrate, said assembly and the substrate forming an integral structure having two separate layers, characterized in that the amount of cross-linking agent is greater than or equal to 5% of the total weight of the composition.

This composition has the advantage of being cross-linkable and adhesive, even in the absence of coupling agents. In particular, it can be used as a masterbatch for cross-linking a polymer, in particular polyolefins, of which it is desired to increase the capacity for adhesion to substrates such as polymers, metals, metal oxides or silicon.

Preferentially, the amount of cross-linking agent is included in the range of from 6 to 30% of the total weight of the composition, preferentially from 7 to 16%.

The cross-linking agent is, for example, an organic peroxide.

Even though its presence is not obligatory, the composition may also comprise a coupling agent, which is an agent capable of increasing the adhesive power of the composition.

The polyolefin is preferentially a polymer of:
ethylene;
at least one functional monomer (X) selected from (meth)acrylic acid, maleic anhydride and glycidyl (meth)acrylate;
and, optionally, an additional monomer comprising from 4 to 20 carbon atoms, selected from carboxylic acid vinyl esters or alkyl (meth)acrylates.

Preferentially, the polyolefin comprises, relative to its total weight:
from 0.01 to 20% by weight of the functional monomer (X);
from 0 to 45% by weight of the additional monomer;
from 99.99 to 35% by weight of ethylene.

For example, the polyolefin comprises, relative to its total weight:
from 0.05 to 10% by weight of the functional monomer (X);
from 10 to 35% by weight of the additional monomer;
from 89.5 to 55% by weight of ethylene.

The functional monomer (X) included in the polyolefin may be inserted therein by grafting or by copolymerization.

The functional monomer (X) may be maleic anhydride.

According to one aspect of the invention, the substrate (24) is made of glass, poly(methyl methacrylate) (PMMA) or any other polymer composition which combines these characteristics.

Another subject of the invention is a preferred process for producing the composition according to the invention, comprising:
a first step of bringing the cross-linking agent in the form of a solution into contact with the polyolefin carrying the functional monomer;
a second step of absorption of the solution of peroxide (b) by the polyolefin with stirring and at a temperature below the softening temperature of the polyolefin carrying the functional monomer, measured according to standard ASTM E 28-99 (2004);
a third step of recovering the composition.

When using processes carried out in the molten state, i.e. when blending the compounds at a temperature above the softening temperature, a phenomenon of premature cross-linking of the composition can be observed because the peroxide activation temperature can be below the processing temperature (such as, for example, according to the process described in documents U.S. Pat. No. 5,589,526, U.S. Pat. No. 3,594,342 and EP 1956661 A1). An advantage of this preferred process is that, compared with the processes carried out in the molten state, the phenomenon of premature cross-linking of the composition is limited and the production process is simple.

The composition obtained by means of this preferred process is also a subject of the invention.

The composition can be advantageously used as a masterbatch for cross-linking a polymer termed “second polymer”, preferentially a polyolefin termed “second polyolefin”.

Another subject of the invention is a film obtained by means of a production process comprising a step of blending a polyolefin with the composition according to the invention to produce a mixture and a step of making said mixture into the form of a film. The resulting film can be used as a photovoltaic cell encapsulant. Thus, the present invention also relates to the use of a film, consisting of a structure obtained from the composition according to any one of claims 1 to 11 having cross-linked with a second polyolefin, as a photovoltaic cell encapsulant.

The invention also relates to a process for producing a photovoltaic module, comprising:
a step of assembling the various layers constituting the module comprising the encapsulating film and photovoltaic cells;
a step of curing the module.

Other advantages are described in detail in the description of the invention hereinafter.

### BRIEF DESCRIPTION OF THE FIGURES

FIG. 1, which has already been described, represents an example of a photovoltaic cell unit, the parts (a) and (b) being ¾ views, the part (a) showing a cell before connection and the part (b) a view after connection of 2 cells; the part (c) is a view from above of a complete photovoltaic cell unit.

FIG. 2, which has already been described, represents a transverse section of a solar module.

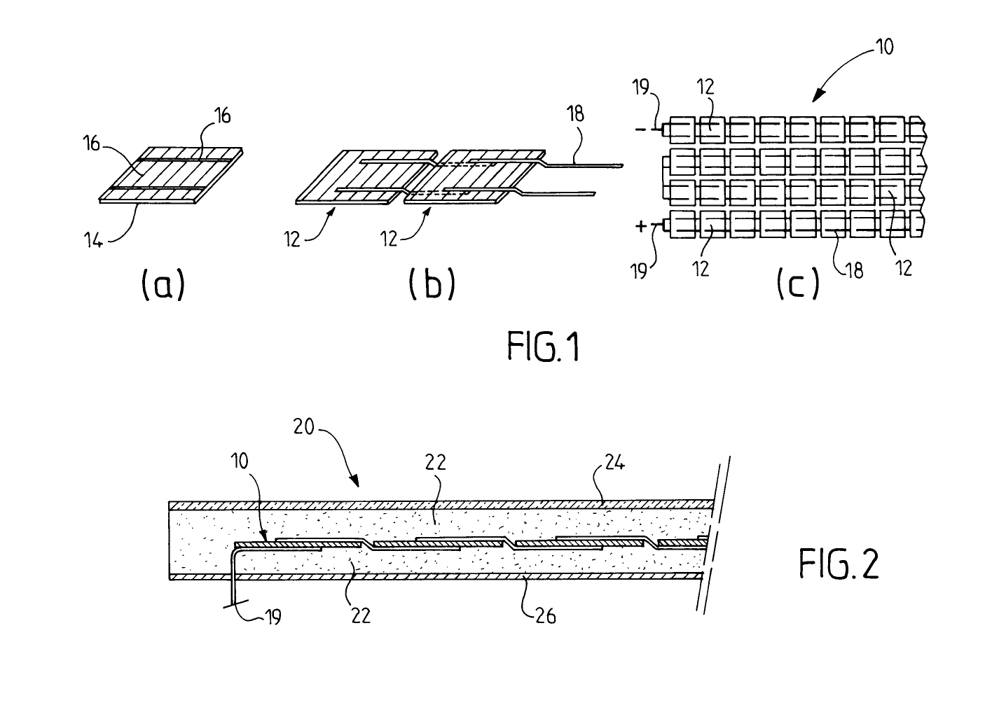

### DETAILED DESCRIPTION OF THE INVENTION

The composition according to the invention comprises a mixture of a cross-linking agent and a polyolefin comprising a functional monomer (X) selected from unsaturated carboxylic acid or dicarboxylic acid anhydrides, unsaturated carboxylic acids and unsaturated epoxides.

Organic peroxides are particularly advantageous cross-linking agents capable of cross-linking polymers such as polyolefins when they are subjected to heat. The term “organic peroxide” is intended to mean any hydrocarbon-based molecule comprising a function of peroxy O—O type. These peroxides take a solid or liquid form. The organic peroxide can also be placed in solution with an organic solvent. Mixtures of peroxides can also be used.

The organic peroxide can be advantageously selected from the families of dialkyl peroxides or peroxy esters.

The organic peroxide is preferentially selected from tert-butyl 2-ethylperhexanoate, di-t-amyl peroxide, dicumyl peroxide, t-butyl cumyl peroxide, OO-t-butyl O-(2-ethylhexyl) monoperoxycarbonate, OO-t-pentyl O-(2-ethylhexyl) monoperoxycarbonate, OO-tert-butyl isopropyl monoperoxycarbonate, di-tert-butyl hydro-peroxide, di-tert-amyl hydroperoxide, 2,5-dimethyl-2,5-di(t-butylperoxy)hexane and 2,2-di(t-amylperoxy)-propane.

The peroxide can optionally comprise an organic solvent, such as solvents of alkane, aromatic, alkene, halogenated or alcohol type. Preferentially, the solvent molecules comprise from 1 to 12 carbon atoms. By way of example of solvent, mention may be made of decane, dodecane, 2,4,4-trimethylpentene, α-methyl-styrene, trichloroethylene, toluene, benzene, ethyl-benzene, (1-methylethenyl)benzene, 2-ethylhexanol, isopropanol, t-butyl alcohol or acetone.

A mixture of solvents, for example a mixture of the solvents listed above, can also be used.

Preferentially, the amount of solvent is less than or equal to 25% of the total weight of the solution of organic peroxide (b), or even less than or equal to 10%.

The solvent used is preferentially not a solvent for the copolymer, quite particularly when the amount of solvent in the solution of peroxide is greater than 20% by weight. The term “solvent for the copolymer” is intended to mean a concentration of polymer greater than or equal to 0.05 g per ml of solvent when bringing into contact, for one hour at 23° C., 1 g of copolymer per ml of solvent.

A polyolefin is a polymer obtained from constituent monomers comprising olefins. These olefins can be selected from ethylene, propylene, but-1-ene, pent-1-ene, 1-hexene, hept-1-ene, octene or dec-1-ene. Preferentially, the olefin is ethylene.

The polyolefin of the composition according to the invention comprises a functional monomer (X) selected from unsaturated carboxylic acid anhydrides, unsaturated dicarboxylic acid anhydrides, unsaturated carboxylic acids and unsaturated epoxides.

As unsaturated monomer (X) included in the polyolefin backbone, mention is made of:

The unsaturated epoxides are, for example, aliphatic glycidyl esters and ethers, such as allyl glycidyl ether, vinyl glycidyl ether, glycidyl maleate and glycidyl itaconate, glycidyl acrylate and glycidyl methacrylate. They are also, for example, alicyclic glycidyl esters and ethers, such as 2-cyclohexene-1-glycidyl ether, cyclohexene-4,5-diglycidyl carboxylate, cyclohexene-4-glycidyl carboxylate, 5-norbornene-2-methyl-2-glycidyl carboxylate and endocis-bicyclo(2,2,1)-5-heptene-2,3-diglycidyl dicarboxylate. It is preferred to use glycidyl methacrylate as the unsaturated epoxide.

The unsaturated carboxylic acids are, for example, acrylic acid or methacrylic acid.

The carboxylic acid or dicarboxylic acid anhydrides can be selected, for example, from maleic, itaconic, citra-conic, allylsuccinic, cyclohex-4-ene-1,2-dicarboxylic, 4-methylenecyclohex-4-ene-1,2-dicarboxylic, bicyclo(2,2,1)hept-5-ene-2,3-dicarboxylic and x-methyl-bicyclo(2,2,1)hept-5-ene-2,2-dicarboxylic anhydrides. It is preferred to use maleic anhydride as the anhydride.

The polyolefin may also comprise another monomer capable of copolymerizing with the olefin, termed “additional monomer”. By way of example of an additional monomer, mention may be made of:
an olefin different than the first olefin, it being possible for said different olefin to be selected from those mentioned above;
dienes, such as, for example, 1,4-hexadiene, ethylidene, norbornene or butadiene;
unsaturated carboxylic acid esters, such as, for example, the alkyl acrylates or alkyl methacrylates grouped together under the term alkyl (meth)acrylates. The alkyl chains of these (meth)acrylates can have up to 30 carbon atoms. Mention may be made, as alkyl chains, of methyl, ethyl, propyl, n-butyl, sec-butyl, isobutyl, tert-butyl, pentyl, hexyl, heptyl, octyl, 2-ethylhexyl, nonyl, decyl, undecyl, dodecyl. Methyl, ethyl and butyl (meth)acrylates are preferred as unsaturated carboxylic acid esters;
carboxylic acid vinyl esters. By way of examples of carboxylic acid vinyl esters, mention may be made of vinyl acetate, vinyl versatate, vinyl propionate, vinyl butyrate or vinyl maleate. Vinyl acetate is preferred as carboxylic acid vinyl ester.

According to two variants of the invention, the functional monomer (X) can either be grafted, or be polymerized on the polyolefin.

The polyolefin can be obtained by polymerization of the monomers (olefin, functional monomer (X) and optional additional monomer). This polymerization can be carried out by means of a high-pressure radical process in an autoclave or tubular reactor, these processes and reactors being well known to those skilled in the art. These polymerization processes are known to those skilled in the art and mention may, for example, be made of the processes described in documents FR2498609, FR2569411 and FR2569412.

When the unsaturated monomer (X) is not copolymerized in the polyolefin backbone, it is grafted onto the polyolefin backbone. The grafting is also an operation known per se. The composition would be in accordance with the invention if various functional monomers (X) were copolymerized in and/or grafted onto the polyolefin backbone. These grafted polymers and these copolymers are sold, for example, by the applicant under the brands Lotader® and Orevac®.

By way of example of a polyolefin of which the functional monomer (X) is copolymerized with the polyolefin, mention may be made, as examples, of an ethylene-maleic anhydride copolymer, an ethylene-methyl (meth)acrylate-maleic anhydride copolymer, an ethylene-ethyl (meth)acrylate-maleic anhydride copolymer, an ethylene-butyl (meth)acrylate-maleic anhydride copolymer, an ethylene-vinyl acetate-maleic anhydride copolymer, an ethylene-glycidyl (meth)acrylate copolymer, an ethylene-methyl (meth)acrylate-glycidyl (meth)acrylate copolymer, an ethylene-ethyl (meth)acrylate-glycidyl (meth)acrylate copolymer, an ethylene-butyl (meth)acrylate-glycidyl (meth)acrylate copolymer and an ethylene-vinyl acetate-glycidyl (meth)acrylate copolymer.

By way of example of a polyolefin grafted with a functional monomer (X), mention may be made of polyolefins of ethylene or of propylene, grafted with maleic anhydride. By way of example, mention may be made of the very low density polyethylene having a density ranging from 0.860 to 0.910, or the ethylene-propylene rubbers known under the name EPR (ethylene propylene rubber) and EPDM (ethylene propylene diene monomer) having a density ranging from 0.860 to 0.910.

Advantageously, the polyolefin comprising a functional monomer (X) is selected from an ethylene-methyl (meth)acrylate-maleic anhydride copolymer, an ethylene-ethyl (meth)acrylate-maleic anhydride copolymer, an ethylene-butyl (meth)acrylate-maleic anhydride copolymer and an ethylene-vinyl acetate-maleic anhydride copolymer.

The composition according to the invention may also comprise coupling agents in order to further improve the adhesive power on another substrate, of the composition or of the polymer to be cross-linked. It may be organic, inorganic and more preferentially semi-inorganic semiorganic. Among said coupling agents, mention may be made of organic silanes or titanates, such as, for example, monoalkyl titanates, trichloro-silanes and trialkoxysilanes. Preferentially, the amount of coupling agent is included in the range of from 0 to 2% by weight relative to the total weight of the composition, for example from 0.1 to 1%.

The composition may also comprise inorganic fillers or additives. By way of example of additives, mention may be made of plasticizers, antioxidants or anti-ozone agents, antistatics, dyestuffs, pigments, optical brighteners, heat stabilizers, light stabilizers and flame retardants.

By way of fillers, mention may be made of clay, silica, talc, carbonates such as calcium carbonate, and silicates such as sodium silicate.

The composition according to the invention is produced by blending the cross-linking agent with the polyolefin comprising a functional monomer (X).

This composition can be obtained by means of the conventional techniques for blending thermoplastics, such as kneading or extrusion. Those skilled in the art adjust this temperature to the decomposition temperature of the cross-linking agent so that no great degree of cross-linking occurs. Preferentially, the temperature at which this blending is carried out ranges up to 150° C., preferentially included in the range of from 70 to 110° C. At this temperature, the cross-linking agent cross-linking phenomenon is limited.

According to one alternative of the method for producing the composition, the cross-linking agent is in liquid form and the process comprises:
a. a first step of bringing the cross-linking agent into contact with the polyolefin;
b. a second step of absorption of the cross-linking agent by the polyolefin, optionally with stirring;
c. a third step of recovering the composition.

The first step of bringing into contact can be carried out in any type of container. The container can be left open or be closed after the bringing into contact. The container can be closed in a leaktight or non-leaktight manner. Preferentially, the container is closed in a leaktight manner and has a valve. The cross-linking agent solution is brought into contact with the copolymer by pouring it directly thereon or by means of a dropping system or else by means of a vaporizing system such as a spray.

The absorption step is carried out at a temperature at which the cross-linking agent solution remains liquid, i.e. at a temperature above or equal to the melting point of the cross-linking agent when the latter is used without solvent. It is, however, advantageous for the temperature of the absorption step to be below the softening temperature of the copolymer (a), measured according to standard ASTM E 28-99 (2004). The temperature of the absorption step can be included in the range of from 15 to 50° C. The absorption time is generally included in the range of from 10 to 600 minutes, preferentially from 20 to 240 minutes. The absorption step can be carried out without stirring. This stirring can be carried out by any stirring system, such as, for example, a blade, propeller, screw or ultrasonic system or in a rotary or drum device, such as a dryer.

The invention also relates to the composition obtained by means of such a process. One advantage of using this type of process is that the cross-linking observed during the production is less than when the composition is produced using conventional techniques for blending thermoplastics.

An example of such a process is, for example, described in the application filed by the applicant under number FR 0953978.

This composition can be used as a masterbatch for cross-linking a second polymer, particularly a second polyolefin. Surprisingly and advantageously, this composition according to the invention makes it possible to cross-link the polymer while at the same time providing it with properties of adhesion to a substrate when the polymer is pressed against a substrate.

Any polyolefin can be used as second polyolefin. In particular, ethylene copolymers, preferentially comprising an amount of ethylene included in the range of from 50 to 90% by total weight of the copolymer, can be used. By way of example of an ethylene copolymer, mention may be made of copolymers of ethylene and of an olefin other than ethylene, copolymers of ethylene and of vinyl acetate, copolymers of ethylene and of alkyl (meth)acrylate, copolymers of ethylene and of (meth)acrylic acid or the ethylene copolymers already mentioned that are used for producing the composition according to the invention. The composition can in particular be used for cross-linking copolymers of ethylene and of vinyl acetate. The second polyolefin can also be a mixture of polyolefins.

The polymer to be cross-linked can also comprise a cross-linking co-agent. When a peroxide is activated, it forms free radicals on the polymer, which enables cross-linking of the polymer chains, without the peroxide being integrated into these chains. A cross-linking co-agent operates differently than a peroxide: indeed, it is activated by means of an initiator of free radicals such as organic peroxides. Thus, activated during the decomposition of the peroxide, it then forms cross-linking bridges with the polymer and is therefore integrated into the cross-linked polymer chain, unlike the peroxides.

The co-agent may be monofunctional or polyfunctional. It advantageously carries at least one carbamate, maleimide, acrylate, methacrylate or allyl function. These are substances which advantageously have a molar mass of less than or equal to 1000 g/mol, preferentially less than or equal to 400 g/mol. Allyl carboxylates can be used. The co-agents may be compounds of allyl, diallyl and triallyl type. Advantageously, the cross-linking co-agent is selected from triallyl cyanurate, triallyl isocyanurate, N,N′-m-phenylenedimaleimide, triallyl trimellitate and trimethylolpropane trimethacrylate, preferentially triallyl cyanurate.

The degree of cross-linking of the cross-linked polymer is generally quantified by measuring the gel content. This gel content can be measured using method A of standard ASTM D2765-01 (2006). Advantageously, the gel content of the polymer is greater than or equal to 10, preferentially greater than or equal to 20, for example greater than or equal to 50.

Moreover, a subject of the invention is also a process for producing a film, comprising a step of blending the composition according to the invention with a second polyolefin, followed by a step of forming into a film. During the blending step, conventional blending techniques are used, in particular in devices for processing thermoplastics, such as extruders or mixers. Blending can be carried out at a temperature below the decomposition temperature of the cross-linking agent. The second, forming step is carried out at a temperature below the decomposition temperature of the cross-linking agent. Use may be made of any type of equipment for forming, such as presses, injection molding machines or calenders. The forming can also be carried out simultaneously with the first step, for example by film extrusion, a sheet die being placed at the end of the extruder.

The invention also relates to the film obtained by means of this process. The film according to the invention can have a thickness ranging from 0.1 to 2 mm.

Preferentially, the film is transparent, i.e. a film 500 μm thick has a transmittance of greater than or equal to 80% when it is evaluated according to standard ASTM D1003 for at least a wavelength in the visible range (from 380 to 780 nm), preferentially greater than or equal to 85%, or even 90%.

Another subject of the invention is the use of this film as a photovoltaic cell encapsulant. The film according to the invention has all the characteristics necessary for its use as an encapsulant, i.e. it adheres to and perfectly matches the photovoltaic cell unit and the protective layers, which makes it possible to avoid the presence of air that would limit the output of the solar module. In one very advantageous version, the encapsulant layers (and in particular the upper encapsulant layer) are transparent in accordance with the parameters given in the present description.

Generally, in order to form a photovoltaic module, a first lower encapsulant layer, a photovoltaic cell unit, a second upper encapsulant layer and then a protective frontsheet are successively placed on a protective backsheet. Additional layers may also be found, and in particular layers of binders or of adhesives. It is specified that the film according to the invention can be used in any photovoltaic structure and that this use is obviously not limited to the modules presented in this description.

In order to form the photovoltaic cell unit, use may be made of any type of photovoltaic sensors including “conventional” sensors based on monocrystalline or polycrystalline doped silicon; thin-layer sensors formed, for example, from amorphous silicon, cadmium telluride, copper indium disilenide or organic materials can also be used.

As examples of a backsheet that can be used in the photovoltaic modules, mention may be made, in a nonexhaustive manner, of monolayer or multilayer films based on polyester, or on fluoropolymer (polyvinyl fluoride PVF or polyvinylidene fluoride PVDF). As particular backsheet structure, mention may, for example, be made of fluoropolymer/polyethylene terephthalate/fluoropolymer or else fluoropolymer/poly-ethylene terephthalate/EVA multilayer films.

The protective frontsheet has abrasion- and impact-resistant properties, is transparent and protects the photovoltaic sensors from external moisture. In order to form this layer, mention may be made of glass, poly(methyl methacrylate) (PMMA) or any other polymer composition which combines these characteristics.

Particularly advantageously, the film according to the invention exhibits good adhesion with PMMA in comparison with the conventional encapsulating films.

A subject of the invention is also a process for producing a photovoltaic module, comprising at least:
a step of assembling the various layers constituting the module, comprising the film of the invention and photovoltaic cells;
a step of curing the module.

In order to carry out the step of curing the module, use may be made of any type of pressing technique, such as, for example, hot pressing, vacuum pressing or lamination, in particular thermal lamination. The production conditions will be easily determined by those skilled in the art by adjusting the temperature to the decomposition temperature of the cross-linking agent and the melting point of the polyolefin of the film. For example, the curing temperature may be included in the range of from 80 to 160° C.

In order to produce the photovoltaic modules according to the invention, those skilled in the art may refer, for example, to the Handbook of Photovoltaic Science and Engineering, Wiley, 2003.

The invention will now be illustrated by the following examples. It is specified that these samples are not in any way intended to limit the scope of the present invention.

### Example 1

### Products Used:

An organic peroxide is used. OO-t-butyl O-(2-ethyl-hexyl) monoperoxycarbonate is used as organic peroxide.

Vinyltrimethoxysilane is used as coupling agent.

In order to prepare the masterbatch according to the invention, granules of a copolymer of ethylene, of vinyl acetate and of maleic anhydride comprising, relative to the weight of the polymer, 28% of acetate and 0.8% of anhydride (copolymer 1) are used.

In order to prepare the comparative masterbatches, granules of a copolymer of ethylene and of vinyl acetate comprising 33% by weight of acetate (copolymer 2) are used.

### Composition of the Masterbatches:

The masterbatches have, relative to the total weight of the masterbatch, the following compositions.

| | Exam- | Exam- | Exam- | Exam- | Exam- | Example |
|---|---|---|---|---|---|---|
| Products | ple I1 | ple CP1 | ple I2 | ple CP2 | ple I3 | CP3 |
| Copolymer | 90 | 0 | 89.7 | 0 | 90 | 0 |
| 1 (%) | | | | | | |
| Copolymer | 0 | 90 | 0 | 89.7 | 0 | 89.7 |
| 2 (%) | | | | | | |
| Peroxide | 10 | 10 | 10 | 10 | 10 | 10 |
| (%) | | | | | | |
| Coupling | 0 | 0 | 0.3 | 0.3 | 0 | 0.3 |
| agent (%) | | | | | | |

### Preparation of the Masterbatches:

An absorption onto the copolymer granules is carried out for each of the peroxide solutions.

The organic peroxide (2.2 kg) is brought into contact, on a roller mixer, with the copolymer (19.8 kg) and, optionally, the coupling agent in a closed container at 20° C., the rotational axis of the roller being horizontal, and mixed by rotation of the container at a speed of 10 revolutions per minute.

A first half of the peroxide solution is injected at the beginning of absorption and a second half is added after 30 minutes of absorption.

The polymer particles are recovered after 120 minutes. The absorption of the peroxide solution into the particles is complete.

The particles were assayed after washing for one hour in n-heptane: the amount of peroxide in the copolymer is 10% by total weight of the composition.

### Preparation of Test Specimens

In order to evaluate the masterbatch according to the invention, films of a mixture of 90% by weight of copolymer 2 with 10% by weight of masterbatch (example I1, I2, CP1 or CP2) are prepared. Films of a mixture of 85% by weight of copolymer 1 with 15% by weight of masterbatch I3 and also of a mixture of 85% by weight of copolymer 2 with 15% by weight of masterbatch CP3 are also prepared.

These films obtained from the 4 masterbatches I1, I2, I3, CP1, CP2 or CP3 are prepared on a Haake 1 twin-screw counter-rotating extruder equipped with a film die. The extruder temperature profile is: hopper 20° C.—zone 1: 75—zone 2: 75—film die: 75° C., the screw speed is 80 rpm. Films 8 cm wide are obtained.

### Measurement of Adhesion

### Evaluation of Masterbatches I1, I2, CP1 and CP2: Adhesion on Glass

A multilayer structure composed of glass (approximately 3 mm)/film (0.32 mm)/polyvinylidene fluoride-based backsheet (0.32 mm) is prepared in order to evaluate the adhesion of the 3 types of film. This structure is produced in several steps:
Cleaning of the glass substrate (200×80×3 mm) with alcohol.
Superposing of the layers of the structure with spacers in order to adjust the thickness of the film.
Preheating of the structure for 3 min under a mass of 5 kg in a furnace at 110° C. then pressing, at 5 bar, of the structure in a press at 150° C. for 15 minutes.
Cooling to ambient temperature.
Conditioning of the test specimens for 24 h in an air-conditioned room.

### Evaluation of Masterbatches I3 and CP3: Adhesion on PMMA

The structure with PMMA is prepared according to the same protocol as above, the sole difference being that the substrate, in place of glass, is a sheet of PMMA (200×80×3 mm).

The adhesion is measured by evaluating the structures on a Zwick 1445 dynanometer equipped with a force sensor, at a pull rate of 50 mm/min, for a peeling at 90° C. according to standard ISO 8510-2:1990: Adhesives-Peel test for a flexible bonded-to-rigid test specimen assembly. The test specimens are cut out with a cutter and have a width of 15 mm. The test specimens have the following adhesions:

| | Peeling force | |
|---|---|---|
| Film | (N/15 mm) | Structure type |
| I1 | 75 | Glass |
| I2 | >90 | Glass |
| I3 | 30 | PMMA |
| CP1 | 55 | Glass |
| CP2 | 90 | Glass |
| CP3 | 0 | PMMA |

The tests show that the masterbatch according to the invention makes it possible to produce films which exhibit very good adhesion on substrates such as glass, even in the absence of coupling agent.

Test I3 shows, when it is compared with example CP3, that the masterbatch is particularly advantageous when the substrate is made of PMMA. Thus, one of the advantages of this masterbatch is that it allows adhesion to many substrates.

### Example 2

### Products Used:

OO-t-butyl O-(2-ethylhexyl) monoperoxycarbonate (PEROX 1) and tert-butyl 2-ethylperhexanoate (PEROX 2) are used as organic peroxide.

Vinyltrimethoxysilane is used as coupling agent.

Granules of a copolymer of ethylene, of vinyl acetate and of maleic anhydride comprising, relative to the weight of the polymer, 28% of acetate and 0.8% of anhydride (copolymer 1) are used to prepare the master-batch according to the invention (I1).

Granules of a copolymer of ethylene and of vinyl acetate comprising 33% by weight of acetate (copolymer 2) are used to prepare the comparative masterbatches (CP1). These masterbatches are then diluted in a matrix (M1, M2 and M3) in order to prepare films.

M1: copolymer of ethylene and of vinyl acetate comprising 33% by weight of acetate, melt flow index=45 (190° C., 21.6 kg)

M2: copolymer of ethylene, of vinyl acetate and of maleic anhydride comprising, relative to the weight of the polymer, 28% of acetate and 0.6% of anhydride, MFI=80

M3: copolymer of ethylene, of vinyl acetate and of maleic anhydride comprising, relative to the weight of the polymer, 28% of acetate and 0.5% of anhydride, MFI=45.

### Composition of the Masterbatches:

The masterbatches have, relative to the total weight of the masterbatch, the following compositions:

| Products | Example I1 | Example CP1 | Example I4 |
|---|---|---|---|
| Copolymer 1 (%) | 90 | 0 | 86.5 |
| Copolymer 2 (%) | 0 | 90 | 0 |
| PEROX 1 (%) | 10 | 10 | 0 |
| PEROX 2 (%) | | | 10 |
| Co-agent | | | 3.5 |
| (triallyl | | | |
| cyanurate) | | | |

### Preparation of the Masterbatches:

Absorption onto the copolymer granules is carried out for each of the peroxide solutions.

The organic peroxide (2.2 kg) is brought into contact, on a roller mixer, with the copolymer (19.8 kg) and, optionally, the coupling agent in a closed container at 20° C., the rotational axis of the roller being horizontal, and mixed by rotation of the container at a speed of 10 revolutions per minute.

A first half of the peroxide solution is injected at the beginning of the absorption and a second half is added after 30 minutes of absorption.

The polymer particles are recovered after 120 minutes.

The absorption of the peroxide solution into the particles is complete.

The particles were assayed after washing for one hour in n-heptane: the amount of peroxide in the copolymer is 10% by total weight of the composition.

### Preparation of the Test Specimens

In order to evaluate the masterbatch according to the invention, films are prepared according to the compositions below:

| | Exam- | Exam- | Exam- | Exam- | Exam- | Exam- |
|---|---|---|---|---|---|---|
| Products | ple CP4 | ple I4 | ple I5 | ple I6 | ple I7 | ple I8 |
| MM I1 | | 15 | 15 | 15 | | |
| (%) | | | | | | |
| MM I4 | | | | | 15 | 15 |
| (%) | | | | | | |
| MM CP1 | 15 | | | | | |
| (%) | | | | | | |
| Coupling | 0.3 | | | | | |
| agent | | | | | | |
| M1 | 84.7 | 85 | | | | |
| M2 | | | 85 | | 85 | |
| M3 | | | | 85 | | 85 |

These films obtained from the 3 masterbatches I1, I4 and CP1 are prepared on a Haake 1 twin-screw counter-rotating extruder equipped with a film die. The extruder temperature profile is: hopper 20° C.—zone 1: 75—zone 2: 75—film die: 75° C., screw speed 80 rpm. Films 8 cm wide are obtained.

### Measurement of Adhesion on Glass

A multilayer structure composed of glass (approximately 3 mm)/film (0.32 mm)/polyvinylidene fluoride-based backsheet (0.32 mm) is prepared in order to evaluate the adhesion of the 3 types of films. This structure is prepared in several steps:
Cleaning of the glass substrate (200×80×3 mm) with alcohol.
Superposition of the layers of the structure with spacers in order to adjust the thickness of the film.
Preheating of the structure for 3 min under a mass of 5 kg in a furnace at 110° C., then pressing, under 5 bar, of the structure in a press at 150° C. for 15 minutes.
Cooling to ambient temperature.
Conditioning of the test specimens for 24 h in an air-conditioned room.

### Measurement of Adhesion on PMMA

Cleaning of the PMMA substrate (200×80×3 mm).
Superposition of the layers of the structure with spacers in order to adjust the thickness of the film.
Preheating of the structure for 3 min under a mass of 5 kg in a furnace at 85° C., then pressing, under 5 bar, of the structure in a press at 115° C. for 15 minutes.
Cooling to ambient temperature.
Conditioning of the test specimens for 24 h in an air-conditioned room.

The adhesion is measured by evaluating the structures on a Zwick 1445 dynamometer equipped with a force sensor, at a pull speed of 50 mm/min, for a peeling at 90° C. according to standard ISO 8510-2:1990: Adhesives—Peel test for a flexible bonded-to-rigid test specimen assembly. The test specimens are cut up with a cutter and have a width of 15 mm. The test specimens have the following adhesions:

| | |
|---|---|
| Glass structure | PMMA structure |

| | Peeling force | Standard | Peeling force | Standard |
|---|---|---|---|---|
| Film | (N/15 mm) | deviation | (N/15 mm) | deviation |
| I4 | 140 | 25 | | |
| I5 | 150 | 25 | | |
| I6 | 150 | 25 | 50 | 10 |
| I7 | 130 | 30 | 30 | 4 |
| CP4 | 160 | 20 | 0 | |

The tests show that the masterbatch according to the invention makes it possible to produce films which exhibit very good adhesion on substrates such as glass, even in the absence of coupling agent.

Tests I6 and I7 show, when they are compared with example CP4, that the masterbatch is particularly advantageous when the substrate is made of PMMA (poly(methyl methacrylate)).

1. A composition comprising a mixture of a cross-linking agent and a first polyolefin comprising a functional monomer (X)-selected from unsaturated carboxylic acid or dicarboxylic acid anhydrides, unsaturated carboxylic acids and unsaturated epoxides, capable of being cross-linked with a second polyolefin in order to form an assembly adhered to a substrate, said assembly and the substrate forming an integral structure having two separate layers, wherein the amount of cross-linking agent is greater than or equal to 5% of the total weight of the composition.

2. The composition as claimed in claim 1, in which the amount of cross-linking agent is included in the range of from 6 to 30% of the total weight of the composition.

3. The composition as claimed in claim 1, in which the cross-linking agent is an organic peroxide.

4. The composition as claimed in one of the preceding claims claim 1, further comprising a coupling agent.

5. The composition as claimed in claim 1, in which the functional polyolefin is a polymer of:
ethylene;
at least one functional monomer (X) selected from (meth)acrylic acid, maleic anhydride and glycidyl (meth)acrylate;
and, optionally, an additional monomer comprising from 4 to 20 carbon atoms, selected from carboxylic acid vinyl esters or alkyl (meth)acrylates.

6. The composition as claimed in claim 5, in which the polyolefin comprising a functional monomer (X) comprises, relative to its total weight:
from 0.01 to 20% by weight of the functional monomer (X);
from 0 to 45% by weight of the additional monomer;
from 99.99 to 35% by weight of ethylene.

7. The composition as claimed in claim 6, in which the polyolefin comprising a functional monomer (X) comprises, relative to its total weight:
from 0.1 to 10% by weight of the functional monomer (X);
from 10 to 35% by weight of the additional monomer;
from 89.9 to 55% by weight of ethylene.

8. The composition as claimed in claim 1, in which the functional monomer (X) which is included in the polyolefin is inserted therein by grafting or by copolymerization.

9. The composition as claimed in claim 1, in which the polyolefin comprising a functional monomer (X) is selected from a polyethylene having a density ranging from 0.860 to 0.910 grafted with maleic anhydride, an ethylene-maleic anhydride copolymer, an ethylene-methyl (meth)acrylate-maleic anhydride copolymer, an ethylene-ethyl(meth)acrylate-maleic anhydride copolymer, an ethylene-butyl(meth)acrylate-maleic anhydride copolymer, an ethylene-vinyl acetate-maleic anhydride copolymer, an ethylene-glycidyl (meth)acrylate copolymer, an ethylene-methyl(meth)acrylate-glycidyl(meth)acrylate copolymer, an ethylene-ethyl(meth)acrylate-glycidyl(meth)acrylate copolymer, an ethylene-butyl(meth)acrylate-glycidyl(meth)acrylate copolymer and an ethylene-vinyl acetate-glycidyl(meth)acrylate copolymer.

10. The composition as claimed in claim 1, in which the functional monomer (X) is maleic anhydride.

11. The composition as claimed in claim 1, in which the substrate is made of glass or poly(methyl methacrylate) (PMMA).

12. A method for producing the composition as claimed in claim 1, the method comprising:
a first step of bringing the cross-linking agent in the form of a solution into contact with the polyolefin carrying the functional monomer;
a second step of absorption of the solution by the polyolefin with stirring and at a temperature below the softening temperature of the polyolefin carrying the functional monomer, measured according to standard ASTM E 28-99 (2004);
a third step of recovering the composition.

13. A masterbatch for cross-linking a second polyolefin comprising a composition obtained by the method as claimed in claim 12.

14. A method for producing a film, comprising:
a step of producing a mixture of a polyolefin with the composition as claimed in claim 1; and
a step of forming said mixture into a film.

15. A photovoltaic cell encapsulant comprising a composition as claimed in claim 1, the composition having cross-linked with a second polyolefin.

16. A method for producing a photovoltaic module, comprising at least:
a step of assembling the various constituent layers of the module comprising:
the film obtained as claimed in claim 14,
a substrate, and
a photovoltaic cell unit;
a step of curing the module.
